(19) United States
(12) Patent Application Publication
(10) Pub. No.: US 2024/0250035 A1
(43) Pub. Date: Jul. 25, 2024

(54) SEMICONDUCTOR DEVICES AND METHODS OF MANUFACTURING SEMICONDUCTOR DEVICES

(71) Applicant: Amkor Technology Singapore Holding Pte. Ltd., Singapore (SG)

(72) Inventors: Se Hwan Hong, Gyeonggi-do (KR); Min Su Jeong, Incheon (KR); Gam Han Yong, Incheon (KR); Won Chul Do, Seoul (KR); Ji Hun Lee, Gyeonggi-do (KR); Jae Yoon Kim, Gyeonggi-do (KR); Jin Hyuk Chang, Incheon (KR); Ji Yeon Ryu, Incheon (KR); Dong Hoon Han, Seoul (KR)

(21) Appl. No.: 18/098,806

(22) Filed: Jan. 19, 2023

(51) Int. Cl. H01L 23/538; H01L 21/56; H01L 21/60; H01L 23/00; H01L 23/31; H01L 23/498; H01L 23/522; H01L 23/544

(52) U.S. Cl. CPC H01L 23/5385; H01L 21/56; H01L 21/60; H01L 23/3128; H01L 23/3135; H01L 23/49816; H01L 23/5226; H01L 23/5386; H01L 23/544; H01L 24/08; H01L 24/16; H01L 24/17; H01L 24/27; H01L 24/32; H01L 24/33; H01L 24/48; H01L 2021/60075; H01L 2021/6009; H01L 2224/08113; H01L 2224/16112; H01L 2224/16235; H01L 2224/1703; H01L 2224/17055; H01L 2224/32059; H01L 2224/32225; H01L 2224/3303; H01L 2224/48091; H01L 2224/48105; H01L 2224/48225; H01L 2924/1016; H01L 2924/1811; H01L 2924/182

(57) ABSTRACT

In one example, an electronic device includes a lower substrate comprising a lower substrate upper side and a lower substrate lower side, and an upper substrate comprising an upper substrate upper side and an upper substrate lower side. The electronic device also includes a first electronic component and a second electronic component coupled to the upper substrate upper side. A first device interconnect and a second device interconnect couple the lower substrate upper side to the upper substrate lower side. The electronic device also includes a connect die coupled to the lower substrate upper side that electrically couples the first electronic component to the second electronic component. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, and/or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, 2E, 2F, 2G, 2H, 2I, 2J, 2K, 2L, 2M, 2N, and 2O show cross-sectional views of an example method for manufacturing an example connect die.

FIGS. 3A, 3B, 3C, 3D, 3E, and 3F show cross-sectional views of an example method for manufacturing an example electronic device.

FIGS. 4A, 4B, 4C, 4D, and 4E show cross-sectional views of an example method for manufacturing an example electronic device.

FIG. 5 shows a cross-sectional view of an example electronic device.

FIGS. 6A, 6B, 6C, 6D, 6E, 6F, and 6G show cross-sectional views of an example method for manufacturing an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. Crosshatching lines may be used throughout the figures to denote different parts but not necessarily to denote the same and/or different materials. Throughout the present disclosure, like reference numbers denote like elements. Accordingly, elements with like element numbering may be shown in the figures but may not be necessarily repeated herein for the sake of clarity.

The term “and/or” means any one and/or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}.

The terms “comprises,” “comprising,” “includes,” and “including” are “open ended” terms and specify the presence of the stated features, but do not preclude the presence and/or addition of one and/or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other and/or to describe two elements indirectly connected by one and/or more other elements. For example, if element A is coupled to element B, then element A may be directly contacting element B and/or indirectly connected to element B by an intervening element C. As used herein, the term “coupled” may refer to an electrical coupling and/or a mechanical coupling. Similarly, the terms “over” and/or “on” may be used to describe two elements directly contacting each other and/or to describe two elements indirectly connected by one and/or more other elements.

### DESCRIPTION

Per one aspect of the disclosure, a method of manufacturing an electronic device is provided. The method includes providing a first device interconnect, a second device interconnect, and alignment pads, wherein the alignment pads are laterally between the first device interconnect and the second device interconnect. The method also includes coupling connect die lower interconnects of a connect die to the alignment pads. The method further includes encapsulating the connect die, the first device interconnect, and the second device interconnect with a lower encapsulant; and providing an upper substrate on the lower encapsulant such that a conductive structure of the upper substrate is coupled to the first device interconnect, the second device interconnect, and connect die upper interconnect of the connect die. Moreover, the method includes coupling a first electronic component and a second electronic component to the upper substrate such that the first electronic component is electrically coupled to the second electronic component via the connect die.

Per another aspect of the disclosure, another method of manufacturing an electronic device is provided. The method includes providing a first device interconnect, a second device interconnect, and a base block, wherein the base block is laterally between the first device interconnect and the second device interconnect. The method also includes coupling a lower side of a connect die to an upper side of the base block, and encapsulating the connect die, the first device interconnect, and the second device interconnect with a lower encapsulant. Further, the method includes providing an upper substrate on the lower encapsulant such that a conductive structure of the upper substrate is coupled to the first device interconnect, the second device interconnect, and connect die upper interconnect of the connect die; and coupling a first electronic component and a second electronic component to the upper substrate such that the first electronic component is electrically coupled to the second electronic component via the connect die.

Per yet another aspect of the disclosure, an electronic device is provided. The electronic device includes a lower substrate comprising a lower substrate upper side and a lower substrate lower side, and an upper substrate comprising an upper substrate upper side and an upper substrate lower side. The electronic device also includes a first electronic component and a second electronic component coupled to the upper substrate upper side. A first device interconnect and a second device interconnect couple the lower substrate upper side to the upper substrate lower side. The electronic device also includes a connect die coupled to the lower substrate upper side laterally between the first device interconnect and the second device interconnect. The connect die electrically couples the first electronic component to the second electronic component.

Other examples are included in the present disclosure. Such examples may be found in the figures, in the claims, and/or in the description of the present disclosure.

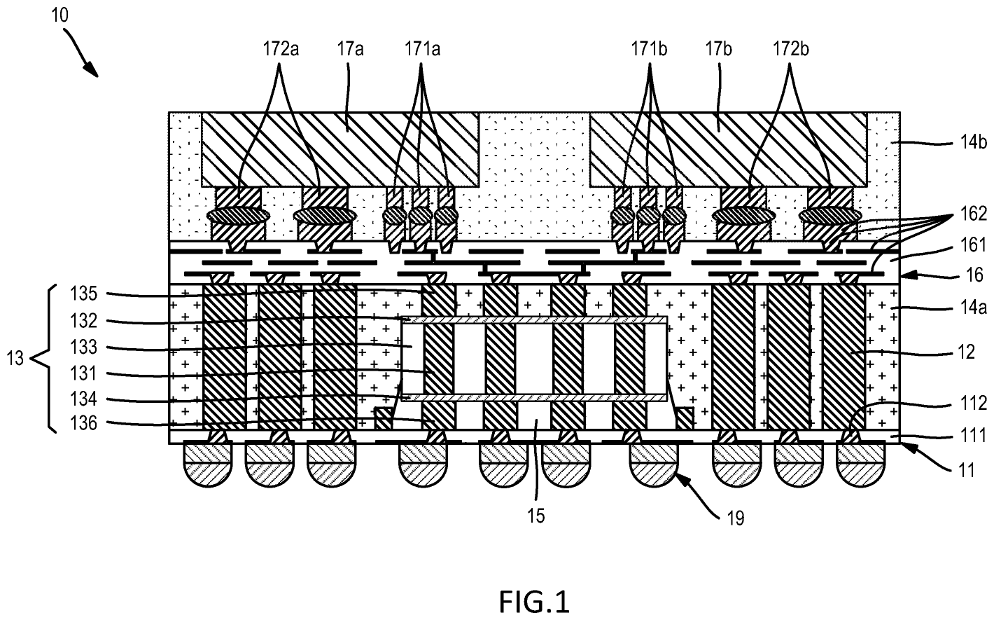

FIG. 1 shows a cross-sectional view of an example electronic device 10. In the example shown in FIG. 1, the electronic device 10 may comprise a lower substrate 11, device interconnects 12, a connect die 13, a lower encapsulant 14a, an upper encapsulant 14b, an interface material 15, an upper substrate 16, a first electronic component 17a, a second electronic component 17b, and external interconnects 19.

The lower substrate 11 may comprise a dielectric structure 111 and a conductive structure 112. The connect die 13 may comprise connect die interconnects 131, a connect die upper redistribution structure (RDS) 132, a connect die body 133, a connect die lower RDS 134, connect die upper interconnects 135, and connect die lower interconnects 136. The upper substrate 16 may comprise a dielectric structure 161 and a conductive structure 162. The first electronic component 17a may comprise first component interconnects 171a, 172a. The second electronic component 17b may comprise second component interconnects 171b, 172b.

The lower substrate 11, the device interconnects 12, the connect die 13, the lower encapsulant 14a, the upper encapsulant 14b, the upper substrate 16, and the external interconnects 19 may be referred to as an electronic package and/or package, and the electronic package may protect electronic components 17a, 17b from exposure to external factors and/or environments. The electronic package may provide couplings between the first electronic component 17a and the second electronic component 17b and between the electronic components 17a, 17b and external components and/or other electronic packages.

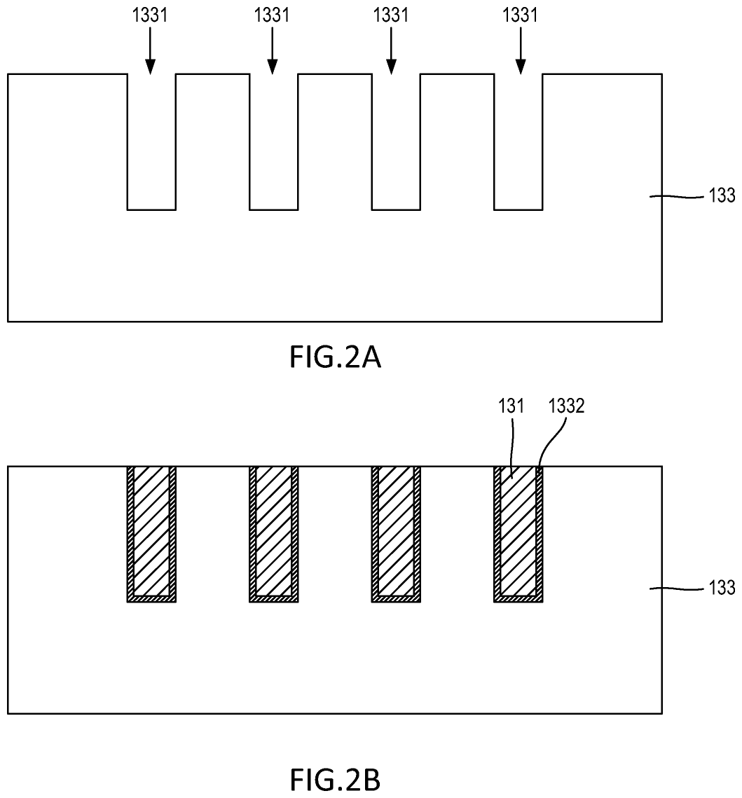

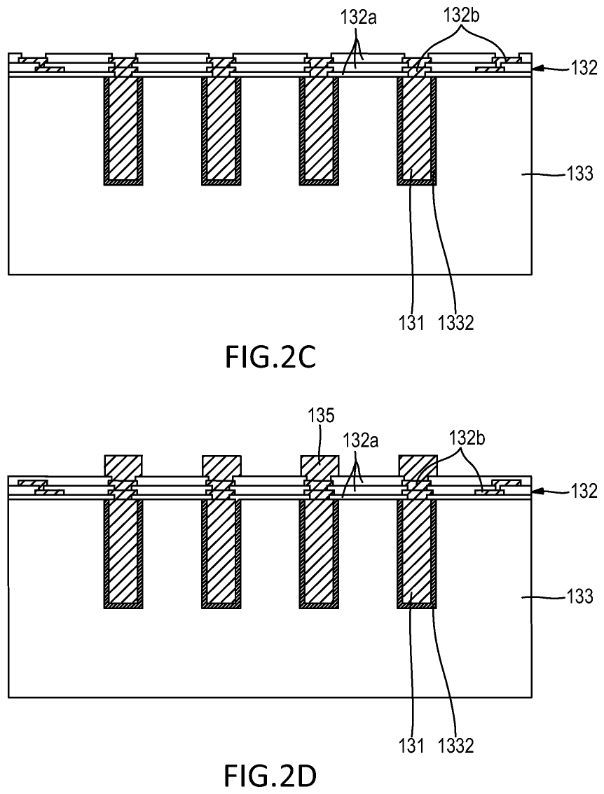

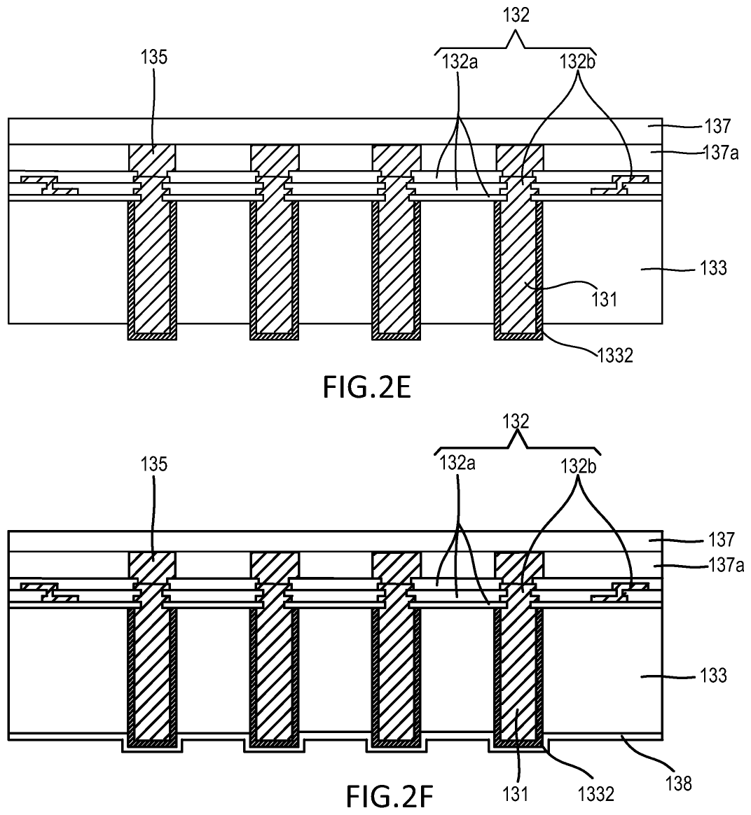

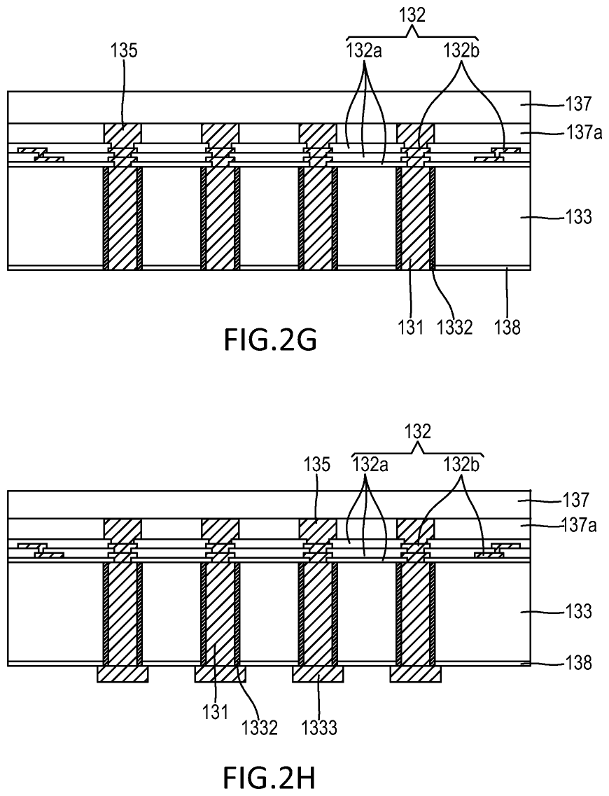

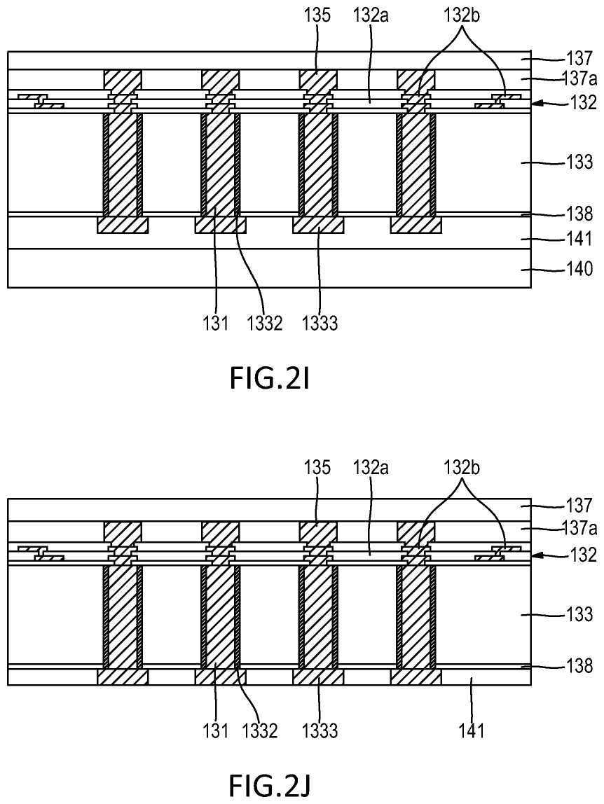

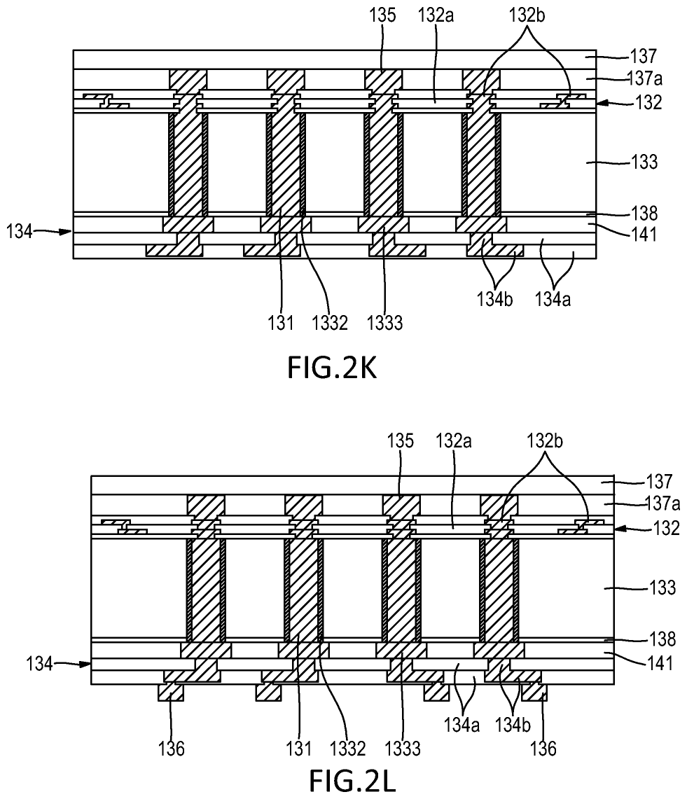

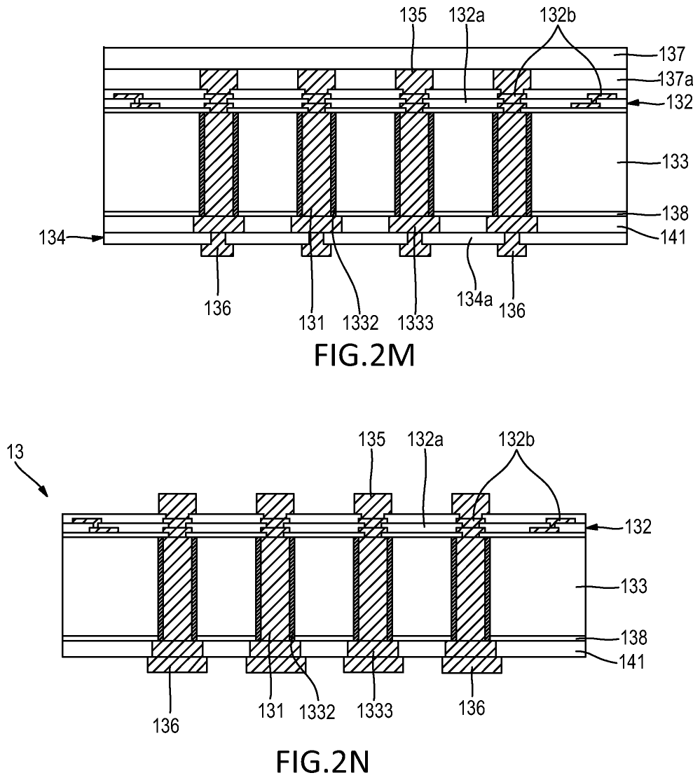

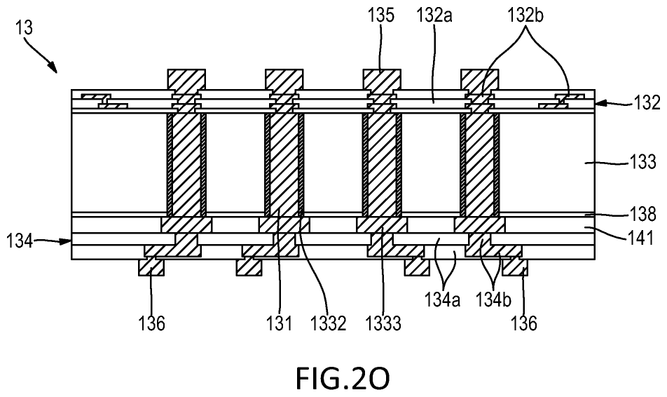

FIGS. 2A to 2O show cross-sectional views of an example method for manufacturing an example connect die, such as connect die 13 in FIG. 1.

FIG. 2A shows a cross-sectional view of connect die 13 at an early stage of manufacture. In the example shown in FIG. 2A, the connect die body 133 may be provided. In some examples, the connect die body 133 may comprise semiconductor conductor material, silicon, glass, oxide, ceramic, and/or an epoxy molding compound. In some examples, the connect die body 133 may be provided in the form and/or a wafer and/or a panel, such that multiple connect die bodies 133 may be provided simultaneously. With momentary reference to FIG. 2O, the connect die body 133 may support connect die interconnects 131, the connect die upper RDS 132, the connect die lower RDS 134, the connect die upper interconnects 135, and the connect die lower interconnects 136, as described in further detail below. In some examples, the thickness of the connect die body 133 may be in the range of about 30 micrometers (μm) to about 300 μm.

Connect die openings 1331 may be provided in the connect die body 133. The connect die openings 1331 may be formed by, for example, deep reactive ion etching (DRIE) and/or by laser beam. In some examples, the diameter of each connect die opening 1331 may be in the range of about 3 μm to about 50 μm, the depth of each connect die opening 1331 may be in the range of about 30 μm to about 300 μm, and the pitch of the connect die openings 1331 may be in the range of about 10 μm to about 100 μm.

FIG. 2B shows a cross-sectional view of connect die 13 at a later stage of manufacture. In the example shown in FIG. 2B, the connect die interconnect liner 1332 may be provided on the inner wall (e.g., the sidewalls and floor) of each connect die opening 1331. The connect die interconnect liner 1332 may comprise one and/or more liner layers. The connect die interconnect liner 1332 may be referred to as a via liner, a barrier layer, and/or a seed layer. In some examples, the connect die interconnect liner 1332 may comprise a structure of three layers sequentially provided on the inner wall of each connect die opening 1331. In some examples, the three-layer structure may include a dielectric layer (e.g., a silicon oxide layer) for insulation between copper and silicon, an adhesion/diffusion prevention layer (e.g., Ta, Ti, and/or W layer) for preventing diffusion of copper that may be fatal to silicon, and a copper seed layer for copper plating. The dielectric layer, adhesion/diffusion prevention layer, and copper seed layer may be sequentially provided in that order on the inner wall of each connect die opening 1331. In some examples, the thickness of connect die interconnect liner 1332 may be in the range of about 1 μm to about 3 μm.

The connect die interconnects 131 may be provided in the connect die openings 1331. The connect die interconnects 131 may comprise and/or be referred to as pillars, posts, and/or conductive vias. In some examples, the connect die interconnects 131 may comprise copper, aluminum, gold, silver, nickel, palladium, and/or solder. In some examples, the connect die interconnects 131 may be provided by electroplating from the inside of the connect die openings 1331 or from the inside of connect die interconnect liner 1332. In some examples, the connect die interconnects 131 may be provided by chemical vapor deposition (CVD), low pressure chemical vapor deposition (LPCVD), physical vapor deposition (PVD), atomic layer deposition (ALD), vacuum plating, evaporation, and/or sputtering. The connect die interconnects 131 may fill the connect die openings 1331 of the connect die body 133. In some examples, the upper sides of the connect die interconnects 131 may be coplanar with the upper side of the connect die body 133. The connect die interconnects 131 may be coupled to the connect die upper RDS 132 and the connect die lower RDS 134, with momentary reference to FIG. 2L. In some examples, the diameter of each connect die interconnect 131 may be in the range of about 3 μm to about 50 μm, the height and/or thickness of the connect die interconnects 131 may be in the range of about 30 μm to about 300 μm, and the pitch of the connect die interconnects 131 may be in the range of about 10 μm to about 100 μm.

FIG. 2C shows a cross-sectional view of the connect die 13 at a later stage of manufacture. In the example shown in FIG. 2C, the connect die upper RDS 132 may be provided. The connect die upper RDS 132 may be provided over the upper side of the connect die body 133 and the connect die interconnects 131. The connect die upper RDS 132 may comprise a dielectric structure 132a and a conductive structure 132b. In some examples, the thickness of the connect die upper RDS 132 may be in the range of about 3 μm to about 50 μm.

The dielectric structure 132a may comprise and/or be referred to as one and/or more dielectrics, dielectric materials, dielectric layers, passivation layers, insulating layers, and/or protective layers. In some examples, dielectric structure 132a may comprise polymer, polyimide (PI), benzocyclobutene (BCB), polybenzoxazole (PBO), bismaleimide triazine (BT), a molding material, phenolic resin, epoxy, silicone, and/or acrylate polymer. Dielectric structure 132a may contact connect die body 133, connect die interconnects 131, and conductive structure 132b. The dielectric structure 132a may expose portions of the conductive structure 132b and the connect die interconnects 131. In some examples, the dielectric structure 132a may maintain the external shape of the connect die upper RDS 132 and may structurally support the conductive structure 132b. In some examples, the dielectric structure 132a may be provided by spin coating, spray coating, printing, oxidation, PVD, CVD, MOCVD, ALD, LPCVD, and/or PECVD. In some examples, the thickness of individual layers of the dielectric structure 132a may be in the range of about 1 μm to about 10 μm. The combined thickness of all layers of the dielectric structure 132a may define the thickness of upper RDS 132.

The conductive structure 132b may comprise and/or be referred to as one and/or more conductors, conductive materials, conductive paths, conductive layers, redistribution layers (RDLs), wiring layers, traces, vias, and/or pads. In some examples, the conductive structure 132b may comprise copper, aluminum, palladium, titanium, tungsten, titanium/tungsten, nickel, gold, and/or silver. The conductive structure 132b may be coupled to connect die interconnects 131. The conductive structure 132b may transmit and/or redistribute a signal, current, and/or voltage through the connect die upper RDS 132. In some examples, the thickness of the conductive structure 132b may be in the range of about 1 μm to about 10 μm. The thickness of the conductive structure 132b may refer to individual layers of the conductive structure 132b.

FIG. 2D shows a cross-sectional view of the connect die 13 at a later stage of manufacture. In the example shown in FIG. 2D, the connect die upper interconnects 135 may be provided on the connect die upper RDS 132. The connect die upper interconnects 135 may comprise and/or be referred to as bumps, pillars, posts, pads, and/or under bump metals (UBMs). The connect die upper interconnects 135 may comprise copper, aluminum, gold, silver, nickel, palladium, and/or solder. The connect die upper interconnects 135 may be coupled to the conductive structure 132b of the connect die upper RDS 132. The connect die upper interconnects 135 may couple the connect die 13 to an external component such as the upper substrate 16 in FIG. 1. In some examples, the connect die upper interconnects 135 may be provided by being plated on the conductive structure 132b of the connect die upper RDS 132. In some examples, the connect die upper interconnects 135 may be provided by CVD, LPCVD, PVD, ALD, vacuum plating, evaporation, and/or sputtering. In some examples, the thickness and/or height of the connect die upper interconnects 135 may be in the range of about 3 μm to about 50 μm. While FIG. 2D shows the connect die upper interconnects 135 as vertically aligned with the connect die interconnects 131, it is contemplated and understood that the connect die upper interconnects 135 may be offset with respect to the connect die interconnects 131. Additionally, in various examples, a first group of the connect die upper interconnects 135 is electrically coupled to the connect die interconnects 131 and a second group of the connect die upper interconnects 135 is electrically isolated from the connect die interconnects 131. Stated differently, one and/or more of the connect die upper interconnects 135 may be electrically isolated from the connect die interconnects 131. For example, a first connect die upper interconnect 135 may be coupled to a second connect die upper interconnect 135 via the conductive structure 132b. The first connect die upper interconnect 135 may be coupled to first electronic component 17a, with momentary reference to FIG. 1, via the upper substrate 16. The second connect die upper interconnect 135 may be coupled to the second electronic component 17b via an upper substrate 16, and both the first connect die upper interconnect 135 and the second connect die upper interconnect 135 may be electrically isolated from the connect die interconnects 131. In this regard, the connect die upper RDS 132 may provide electrical signal paths between the first electronic component 17a and the second electronic component 17b.

FIG. 2E shows a cross-sectional view of the connect die 13 at a later stage of manufacture. In the example shown in FIG. 2E, the connect die 13 may be coupled to an connect die upper carrier 137. In some examples, the connect die upper carrier 137 may comprise a silicon, glass, ceramic, a metal, and/or plastic wafer and/or panel. In some examples, the connect die upper carrier 137 may be in the form of a round disk (e.g., circular or elliptical) or a polygonal plate (e.g., rectangular or square). The connect die upper carrier 137 may support the connect die body 133, the connect die upper RDS 132, and the connect die upper interconnects 135 in later processing, as described in further detail below. In some examples, the connect die bodies 133 may be coupled to the connect die upper carrier 137 in a wafer and/or panel form, in which multiple connect die bodies 133 may be coupled to the connect die upper carrier 137 as a single, integral unit. In some examples, the connect die 13 may be coupled to the connect die upper carrier 137 through a temporary adhesive 137a. In some examples, the temporary adhesive 137a may comprise an adhesive film, an adhesive tape, a thermal release tape, and/or a chemical release tape. In some examples, the connect die upper carrier 137 may be removed and/or release by applying heat, chemical materials, light irradiation, and/or physical force to the temporary adhesive 137a. In some examples, the temporary adhesive 137a may be omitted. In such embodiments, the connect die upper carrier 137 may be coupled to the connect die 113 in a manner similar to coupling the connect die lower carrier 140 to the connect die 113 as described below.

In accordance with various examples, a grinding operation and/or etching process may be performed on the connect die body 133 to expose lower portions of the connect die interconnects 131. For example, lower portions of connect die body 133 opposite the connect die upper carrier 137 and the connect die upper RDS 132 may be removed by grinding. In some examples, the grinding operation may expose the lower portions of the connect die interconnects 131. For example, after grinding, the lower side of the connect die interconnects 131 may be coplanar with the lower side of connect die body 133. In some examples, after grinding, an etching process may be performed and, after etching, the lower portions of the connect die interconnects 131 may protrude from the lower side of connect die body 133. In some examples, the connect die interconnect liner 1332, which surrounds the connect die interconnects 131, may protrude from the lower side of connect die body 133. In this regard, the lower side of the connect die body 133 and the lower side of the connect die interconnects 131 may be located on different planes. For example, the lower side of the connect die body 133 may be on a first plane and the lower side of the connect die interconnects 131 may be on a second, lower plane. In some examples, the thickness (or height) of connect die interconnects 131 may be in the range of about 30 μm to about 300 μm. In some examples, the thickness (or height) of the portions of connect die interconnects 131 extending below the lower side of connect die body 133 may be in the range of about 0.5 μm to about 2.0 μm, about 0.9 μm to about 1.5 μm, or, in some examples, at least 0.9 μm.

FIG. 2F shows a cross-sectional view of the connect die 13 at a later stage of manufacture. In the example shown in FIG. 2F, a connect die lower dielectric layer 138 may be provided. The connect die lower dielectric layer 138 may be provided on the lower side of the connect die body 133 and on the protruding portions of the connect die interconnects 131 and/or the connect die interconnect liner 1332. In some examples, the connect die lower dielectric layer 138 may comprise a silicon nitride (SiN) film, SiN layer, a silicon oxide (SiO₂) film and/or SiO₂ layer. In some examples, the connect die lower dielectric layer 138 may be provided by CVD and/or thermal oxidation using nitrogen gas and/or oxygen gas. The connect die lower dielectric layer 138 may prevent various impurities from penetrating into the connect die body 133 during the manufacturing process of an electronic device. In some examples, the thickness of dielectric layer 138 may be in the range of about 1 μm to about 10 μm.

FIG. 2G shows a cross-sectional view of the connect die 13 at a later stage of manufacture. In the example shown in FIG. 2G, a chemical mechanical polishing (CMP) process may be performed on the connect die interconnects 131. In some examples, the protruding connect die interconnects 131 may be ground or removed until the lower side of the connect die interconnects 131 is exposed. The CMP process may polish/remove at least some of the lower side of the connect die interconnects 131 and the connect die interconnect liner 1332 and portions of the connect die lower dielectric layer 138 surrounding the lower side of the connect die interconnects 131 and the connect die interconnect liner 1332. The connect die interconnects 131 may be exposed at the lower side of connect die body 133. The exposed lower sides of the connect die interconnects 131 may be coplanar with the connect die lower dielectric layer 138 on the lower side of the connect die body 133.

FIG. 2H shows a cross-sectional view of the connect die 13 at a later stage of manufacture. In the example shown in FIG. 2H, connect die pads 1333 may be provided on the lower side of the connect die interconnects 131. The connect die pads 1333 may comprise and/or be referred to as lands, pillars, posts, and/or UBM. In some examples, a width of the connect die pad 1333 is greater than the diameter of its respective connect die interconnect 131. The connect die pads 1333 may comprise copper, aluminum, gold, silver, nickel, palladium, and/or solder. The connect die pads 1333 may be coupled to the connect die interconnects 131. In some examples, the connect die pads 1333 may be provided by being plating, CVD, LPCVD, PVD, ALD, vacuum plating, evaporation, and/or sputtering. In some examples, the thickness and/or height of the connect die pads 1333 may be in the range of about 3 μm to about 50 μm.

FIG. 2I shows a cross-sectional view of the connect die 13 at a later stage of manufacture. In the example shown in FIG. 2I, a connect die lower carrier 140 may be provided. The connect die lower carrier 140 may comprise a silicon, glass, ceramic, metal, and/or plastic wafer and/or panel. The connect die lower carrier 140 may include a connect die insulating layer 141. The connect die insulating layer 141 may comprise a non-conductive, electrically insulating material. For example, the connect die insulating layer 141 may comprise a nonconductive paste and/or nonconductive film. The connect die insulating layer 141 may be provided over an upper side of the connect die lower carrier 140 such that the connect die insulating layer 141 is positioned between the connect die lower carrier 140 and the lower side of the connect die body 133. The connect die insulating layer 141 may contact the connect die lower dielectric layer 138 and the connect die pads 1333. The connect die insulating layer 141 may surround the lateral sides and the lower sides of the connect die pads 1333. The connect die insulating layer 141 may be pliable, at least initially, such that the connect die pads 1333 may be inserted into the connect die insulating layer 141 by pressing the connect die lower carrier 140 and the connect die insulating layer 141 toward the connect die body 133.

FIG. 2J shows a cross-sectional view of the connect die 13 at a later stage of manufacture. In the example shown in FIG. 2J, the connect die lower carrier 140 is removed. In some examples, a lower portion of the connect die insulating layer 141 is also removed, thereby exposing the lower side of the connect die pads 1333. In various examples, the lower side of the connect die pads 1333 may be coplanar with the lower side of the connect die insulating layer 141. The connect die lower carrier 140 and the lower portion of the connect die insulating layer 141 may be removed by grinding, laser, etching, and/or any other suitable removal technique.

FIG. 2K shows a cross-sectional view of the connect die 13 at a later stage of manufacture. In the example shown in FIG. 2K, the connect die lower RDS 134 may be provided. The connect die lower RDS 134 may be provided on the lower side of connect die pads 1333 and connect die insulating layer 141. The connect die lower RDS 134 may comprise a dielectric structure 134a and a conductive structure 134b. In some examples, the thickness of the connect die lower RDS 134 may be in the range of about 3 μm to about 50 μm.

The dielectric structure 134a of the connect die lower RDS 134 may comprise and/or be referred to as one and/or more dielectrics, dielectric materials, dielectric layers, passivation layers, insulating layers, and/or protective layers. In some examples, the dielectric structure 134a may comprise polymer, PI, BCB, PBO, BT, a molding material, phenolic resin, epoxy, silicone, and/or acrylate polymer. The dielectric structure 134a may contact the connect die insulating layer 141, the connect die pads 1333, and the conductive structure 134b of the connect die RDS 134. In some examples, the dielectric structure 134a may maintain the external shape of the connect die lower RDS 134 and may structurally support the conductive structure 134b. In some examples, the dielectric structure 134a may be provided by spin coating, spray coating, printing, oxidation, PVD, CVD, MOCVD, ALD, LPCVD, and/or PECVD. In some examples, the thickness of the dielectric structure 134a may be in the range of about 1 μm to about 10 μm. The combined thickness of all layers of the dielectric structure 134a may define the thickness of lower RDS 134.

The conductive structure 134b of the connect die lower RDS 134 may comprise and/or be referred to as one and/or more conductors, conductive materials, conductive paths, conductive layers, redistribution layers, wiring layers, traces, vias, and/or pads. In some examples, the conductive structure 134b may comprise copper aluminum, palladium, titanium, tungsten, titanium/tungsten, nickel, gold, and/or silver. The conductive structure 134b may be coupled to connect die pads 1333. The conductive structure 134b may be coupled to the connect die interconnects 131 via the connect die pads 1333. The conductive structure 134b may transmit and/or redistribute a signal, current, and/or voltage within the connect die lower RDS 134. In some examples, the thickness of the conductive structure 134b may be in the range of about 1 μm to about 20 μm. The thickness of the conductive structure 134b may refer to individual layers of the conductive structure 134b.

FIG. 2L shows a cross-sectional view of the connect die 13 at a later stage of manufacture. In the example shown in FIG. 2L, the connect die lower interconnects 136 may be provided on a lower side of the connect die lower RDS 134. The connect die lower interconnects 136 may comprise and/or be referred to as bumps, pillars, posts, pads, and/or UBMs. The connect die lower interconnects 136 may comprise copper, aluminum, gold, silver, nickel, palladium, and/or solder. The connect die lower interconnects 136 may couple the connect die 13 to external components such as the external interconnects 19 in FIG. 1. In some examples, the connect die lower interconnects 136 may be provided by being plated on the conductive structure 134b of connect die lower RDS 134. In some examples, the connect die lower interconnects 136 may be provided by CVD, LPCVD, PVD, ALD, vacuum plating, evaporation, and/or sputtering. In some examples, the thickness of the connect die lower interconnects 136 may be in the range of about 3 μm to about 50 μm. In some examples, one and/or more of the connect die upper interconnects 135 may be coupled to the connect die lower interconnects 136 via, at least, the connect die interconnects 131.

With reference to FIG. 2M, in some examples, the connect die lower interconnects 136 may be provided on or in contact with the connect die pads 1333. For example, the dielectric structure 134a of the connect die lower RDS 134 may be formed on connect die pads 1333 and the connect die insulating layer 141. The dielectric structure 134a may define openings that expose the connect die pads 1333. Moreover, the connect die lower interconnects 136 may be provided in the openings of the dielectric structure 134a and on connect die pads 1333.

With reference to FIG. 2N, in some examples, the connect die lower interconnects 136 may be provided on or in contact with the connect die pads 1333 and the connect die insulating layer 141. In some examples, the connect die lower interconnects 136 may extend over the connect die insulating layer 141. In some examples, the connect die insulating layer 141 may extend over the connect die pads 1333 and may define openings that expose the connect die pads 1333, similar to dielectric structure 134a in FIG. 2M.

Continuing from FIG. 2L, FIG. 2O shows a cross-sectional view of the connect die 13 at a later stage of manufacture. In the example shown in FIG. 2O, the connect die upper carrier 137 may be removed, and the connect die 13 may be provided. In some examples, when a temporary adhesive is interposed between the connect die upper RDS 132 and the connect die upper carrier 137, heat and/or light may be provided to the temporary adhesive, thereby weakening, and/or removing, the adhesive force of the temporary adhesive, and thus the connect die upper carrier 137 may be removed from the connect die upper RDS 132. In some examples, the connect die upper carrier 137 may be forcibly peeled from the connect die upper RDS 132 by a mechanical force. In some examples, the connect die upper carrier 137 may be removed by mechanical grinding and/or chemical etching. If the connect die 13 are in panel and/or wafer form, the connect die 13 may be singulated (e.g., using a saw and/or laser) into individual connect die 13.

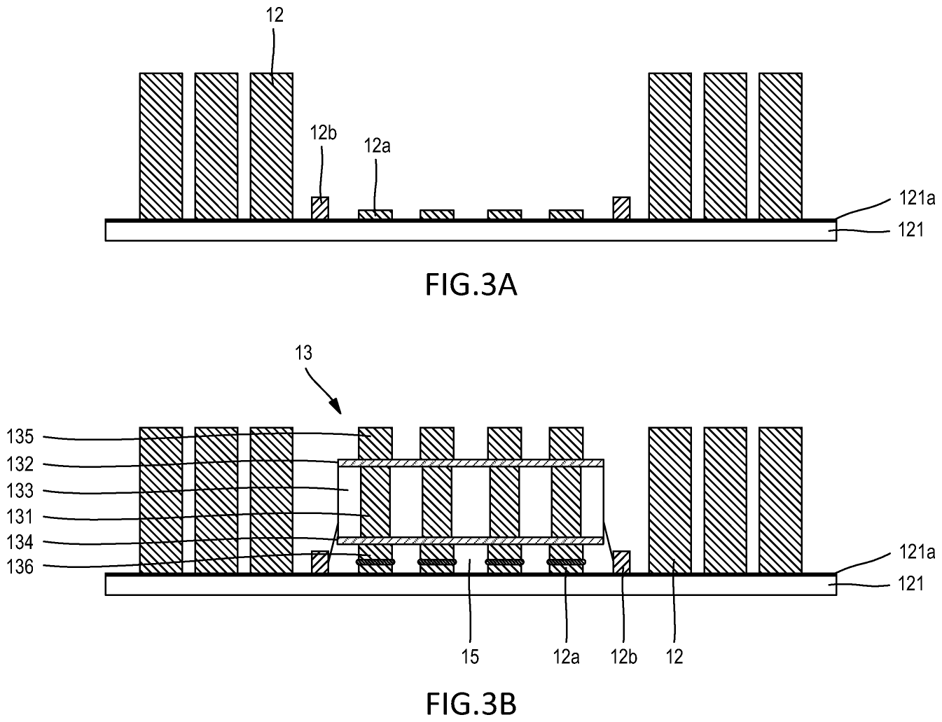

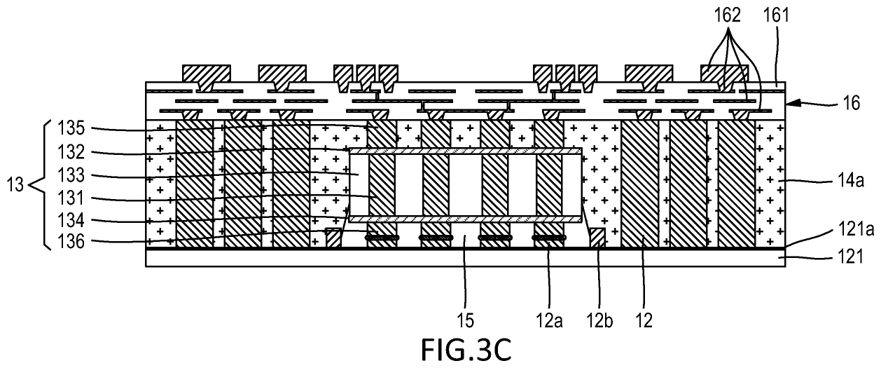

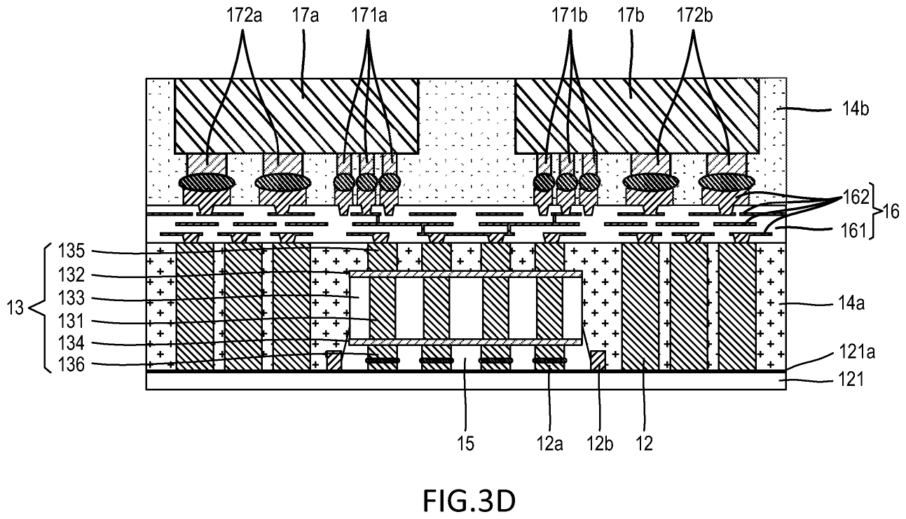

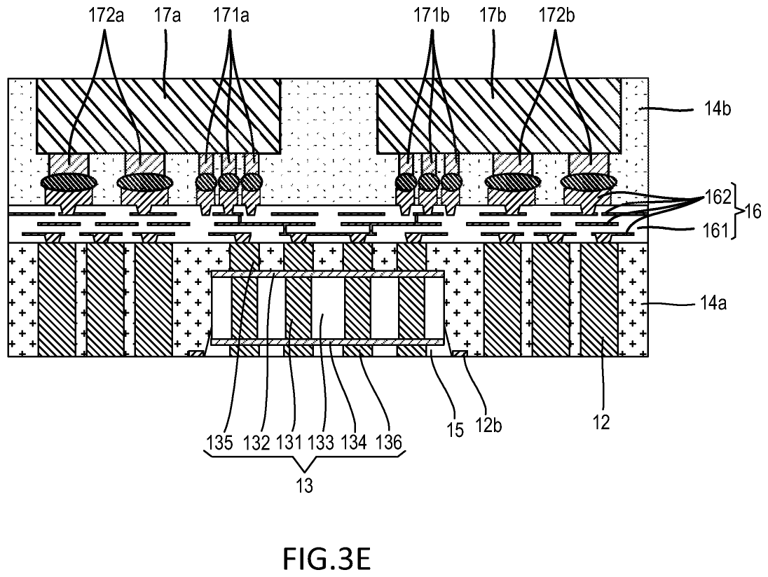

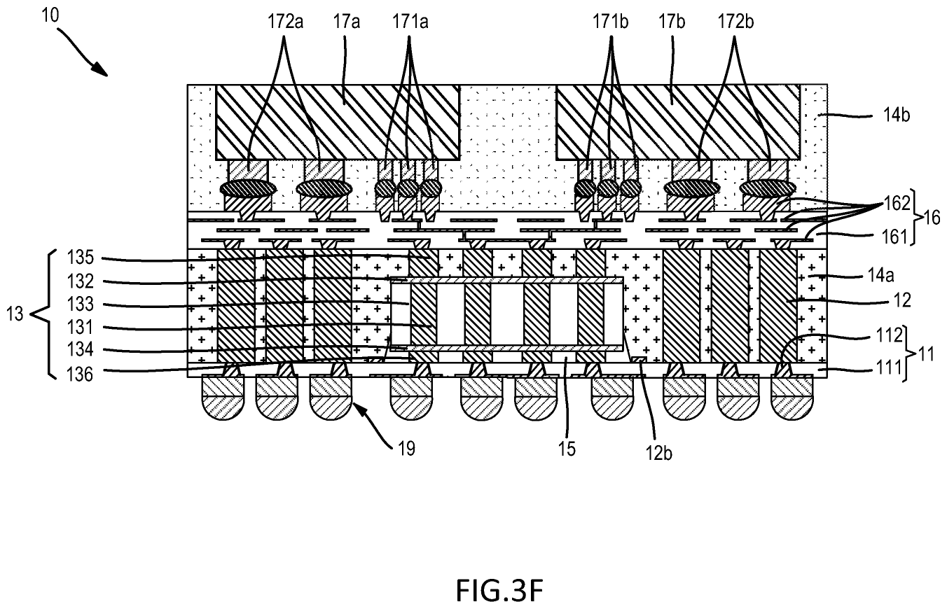

FIGS. 3A to 3F show cross-sectional views of an example method for manufacturing the electronic device 10 of FIG. 1.

FIG. 3A shows a cross-sectional view of the electronic device 10 at an early stage of manufacture. In the example shown in FIG. 3A, the device interconnects 12 may be provided on a device carrier 121. In some examples, the device carrier 121 may comprise a silicon, glass, ceramic, metal, and/or plastic wafer and/or panel. In some examples, the device carrier 121 may be in the form of a round disk (e.g., circular or elliptical) or polygonal plat (e.g., rectangular or square). The device carrier 121 may support the device interconnects 12, the connect die 13, the lower encapsulant 14a, and the upper substrate 16 during processing, as described below.

A seed layer 121a may be provided on the device carrier 121. In some examples, the seed layer 121a may comprise copper, aluminum, gold, silver, nickel, palladium, and/or solder. In some examples, the seed layer 121a may be provided by CVD, LPCVD, PVD, ALD, vacuum plating, evaporation, and/or sputtering. The seed layer 121a may be provided as an electrical path when forming the device interconnects 12 on the device carrier 121. In some examples, the thickness of the seed layer 121a may be in the range of about 0.05 μm to about 1 μm.

In some examples, the device interconnects 12 may be provided on the seed layer 121a. The device interconnects 12 may comprise and/or be referred to as pillars and/or posts. In some examples, the device interconnects 12 may comprise copper, aluminum, gold, silver, nickel, palladium, and/or solder. In some examples, the device interconnects 12 may be provided by being electrolytically plated on the seed layer 121a. In some examples, the device interconnects 12 may also be provided by CVD, LPCVD, PVD, ALD, vacuum plating, evaporation, and/or sputtering. In some examples, the device interconnects 12 may be provided as a connection path between the lower substrate 11 and upper substrate 16. In some examples, the height of the device interconnects 12 may be in the range of about 30 μm to about 300 μm, and the pitch of the device interconnects 12 may be in the range of about 30 μm to about 300 μm.

In some examples, alignment pads 12a may be provided on the seed layer 121a. The alignment pads 12a may comprise and/or be referred to as pads, lands, and/or terminals. In some examples, the alignment pads 12a may comprise copper, aluminum, gold, silver, nickel, palladium, and/or solder. In some examples, the alignment pads 12a may be provided by being electrolytically plated on the seed layer 121a. In some examples, the alignment pads 12a may also be provided by CVD, LPCVD, PVD, ALD, vacuum plating, evaporation, and/or sputtering. The alignment pads 12a may be provided laterally between opposing device interconnects 12. In some examples, the thickness of alignment pads 12a may be in the range of about 0.05 μm to about 10 μm.

In some examples, alignment features 12b may be provided on the seed layer 121a. The alignment features 12b may be provided laterally between opposing device interconnects 12 with the alignment pads 12a laterally between opposing alignment features 12b. In some examples, the alignment features 12b may comprise and/or be referred to as alignment fiducials, metal fiducials, pillars, posts, pads, and/or traces. In some examples, the alignment features 12b may comprise a metallic and/or dielectric material. For example, the alignment features 12b may comprise a metallic material, such as copper, aluminum, gold, silver, nickel, and/or palladium, and/or a dielectric material, such as polymer, PI, BCB, PBO, BT, a molding material, phenolic resin, epoxy, silicone and/or acrylate polymer. In some examples, the alignment features 12b may be provided by being electrolytically plated on the seed layer 121a. In some examples, the alignment features 12b may be provided by CVD, LPCVD, PVD, ALD, vacuum plating, evaporation, and/or sputtering. The height of the alignment features 12b may be provided to be higher than the height of the alignment pads 12a and lower than the height of the device interconnects 12. In some examples, the height of the alignment features 12b may be in the range of about 1 μm to about 30 μm.

FIG. 3B shows a cross-sectional view of the electronic device 10 at a later stage of manufacture. In the example shown in FIG. 3B, the connect die 13 may be provided on the device carrier 121. In some examples, the device interconnects 12 may be located outside the connect die 13. The alignment pads 12a may be coupled to the connect die lower interconnects 136. In some examples, the connect die lower interconnects 136 may be coupled to the alignment pads 12a via solder. In some examples, the connect die 13 and its connect die lower interconnects 136 may be coupled to the alignment pads 12a by a mass reflow process, a thermal compression process, and/or a laser bonding process. In some examples, the alignment features 12b may be a reference point and/or identification point for guiding and/or centering the connect die 13 and/or identifying the attachment position of the connect die 13, when coupling the connect die 13 to the device carrier 121. In some examples, the upper sides of the connect die upper interconnects 135 may be coplanar with the upper sides of the device interconnects 12.

The interface material 15 may be provided between the connect die 13 and the device carrier 121. In some examples, the interface material 15 may comprise and/or be referred to as underfill, insulating paste, and/or non-conductive paste. The interface material 15 may surround the connect die lower interconnects 136 and the alignment pads 12a. In some examples, the alignment features 12b may retain the interface material 15 between inner lateral sides of the alignment features 12b and thus prevent the interface material 15 from flowing towards the device interconnects 12. The interface material 15 may be in contact with the inner sides of the alignment features 12b, the lower side of the connect die 13, and the seed layer 121a. In some examples, the interface material 15 may cover a portion of the lateral side of the connect die 13. In some examples, after the connect die 13 is bonded to the alignment pads 12a, the interface material 15 may be provided between the connect die 13 and the device carrier 121 and then cured. In some examples, the interface material 15 may be applied to cover the alignment pads 12a, and during connection of the connect die 13, the connect die lower interconnects 136 may penetrate through the interface material 15 and be coupled to the alignment pads 12a. In some examples, the thickness of the interface material 15 may be in the range of about 3 μm to about 50 μm.

FIG. 3C shows a cross-sectional view of the electronic device 10 at a later stage of manufacture. In the example shown in FIG. 3C, the lower encapsulant 14a may be provided over the device carrier 121. The lower encapsulant 14a may cover the device carrier 121, the device interconnects 12, and the connect die 13. The lower encapsulant 14a may comprise and/or be referred to as a mold material, a protective material, a mold compound, and/or resin. In some examples, the lower encapsulant 14a may comprise a polymer composite material, a polymer having an inorganic filler, an epoxy resin, an epoxy resin having a filler, an epoxy acrylate having a filler, and/or a silicone resin. In some examples, the lower encapsulant 14a may be provided by a compression molding process, a vacuum lamination process, a liquid phase encapsulant molding process, a paste printing process, and/or a film assisted molding process. In some examples, the height of the lower encapsulant 14a may be in the range of about 30 μm to about 300 μm.

In some examples, the height and/or thickness of the lower encapsulant 14a may be greater than the heights and/or thicknesses of the device interconnects 12, the height and/or thickness of the connect die 13, and/or the height of the connect die upper interconnects 135. In this case, a grinding process and/or a chemical etching process for removing an upper portion of lower encapsulant 14a may be performed. In some examples, the grinding process, may expose the upper sides of the device interconnects 12 and upper sides of the connect die upper interconnects 135 at the upper side of the lower encapsulant 14a. In some examples, the upper sides of the device interconnects 12 and the upper sides of the connect die upper interconnects 135 may be coplanar with the upper side of the lower encapsulant 14a.

In some examples, performing the grinding in a state where the connect die 13 is surrounded by the lower encapsulant 14a, tends to distribute the stress applied to the upper side of the connect die 13 to the upper side of the lower encapsulant 14a, which may reduce and/or prevent damage (e.g., edge cracking) to the upper side of the connect die 13 during the grinding process.

With the upper sides of the device interconnects 12 and the upper sides of the connect die upper interconnects 135 exposed, the upper substrate 16 may be provided over the device interconnects 12, the lower encapsulant 14a, and the connect die 13. The upper substrate 16 may be provided on the upper side of the lower encapsulant 14a. In some examples, the upper substrate 16 may cover the device interconnects 12, the lower encapsulant 14a, and the connect die 13. The upper substrate 16 may comprise and/or be referred to as a redistribution structure. The upper substrate 16 may comprise a dielectric structure 161 and a conductive structure 162. In some examples, the thickness of the upper substrate 16 may be in the range of about 3 μm to about 50 μm.

The dielectric structure 161 of the upper substrate 16 may comprise one and/or more dielectrics, dielectric materials, dielectric layers, passivation layers, insulating layers, and/or protective layers. In some examples, the dielectric structure 161 may comprise polymer, PI, BCB, PBO, BT, a molding material, phenolic resin, epoxy, silicone and/or acrylate polymer. The dielectric structure 161 may be in contact with the device interconnects 12, the lower encapsulant 14a, the connect die upper interconnects 135, and the conductive structure 162 of the upper substrate 16. The dielectric structure 161 may expose portions of the conductive structure 162, the connect die upper interconnects 135, and the device interconnects 12. In some examples, the dielectric structure 161 may maintain the external shape of the upper substrate 16 and may structurally support the conductive structure 162. In some examples, the dielectric structure 161 may be provided by spin coating, spray coating, printing, oxidation, PVD, CVD, MOCVD, ALD, LPCVD, and/or PECVD. In some examples, the thickness of individual layers of the dielectric structure 161 may be in the range of about 1 μm to about 10 μm. The combined thickness of all layers of dielectric structure 161 may define the thickness of upper substrate 16.

The conductive structure 162 of the upper substrate may comprise one and/or more conductors, conductive materials, conductive paths, conductive layers, RDLs, wiring layers, traces, vias, pads, bumps, pillars, posts, and/or UBMs. In some examples, the conductive structure 162 may comprise copper, aluminum, palladium, titanium, tungsten, titanium/tungsten, nickel, gold, and/or silver. The conductive structure 162 may be coupled to connect die upper interconnects 135 and the device interconnects 12. The conductive structure 162 may transmit and/or redistribute signals, currents, and/or voltages within the upper substrate 16. In some examples, the thickness of the conductive structure 162 may be in the range of about 1 μm to about 10 μm. The thickness of the conductive structure 162 may refer to individual layers of the conductive structure 162.

FIG. 3D shows a cross-sectional view of the electronic device 10 at a later stage of manufacture. In the example shown in FIG. 3D, the electronic components 17a, 17b may be provided on upper substrate 16. The first electronic component 17a may comprise first component fine-pitch interconnects 171a and first component coarse-pitch interconnects 172a. In some examples, the first component fine-pitch interconnects 171a may have a pitch of about 5 μm to about 50 μm and the first component coarse-pitch interconnects 172a may have a pitch of about 10 μm to about 100 μm. The pitch of the first component fine-pitch interconnects 171a is smaller than the pitch of first component coarse-pitch interconnects 172a. Thus, the first electronic component 17a may comprise both first component fine-pitch interconnects 171a and first component coarse-pitch interconnects 172a, which may couple the first electronic component 17a to the conductive structure 162 of the upper substrate 16.

The second electronic component 17b may comprise second component interconnects 171b, 172b. In some examples, the second component fine-pitch interconnects 171b may have a pitch of about 5 μm to about 50 μm and the second component coarse-pitch interconnects 172b may have a pitch of about 10 μm to about 100 μm. The pitch of the second component fine-pitch interconnects 171b is smaller than the pitch of second component coarse-pitch interconnects 172b. Thus, the second electronic component 17b may comprise both second component fine-pitch interconnects 171b and second component coarse-pitch interconnects 172b, which may couple the second electronic component 17b to the conductive structure 162 of the upper substrate 16. In some examples, the component interconnects 171a, 172a, 171b, 172b may comprise and/or be referred to as bumps, pillars, pillars with solder caps, and/or pads. In some examples, the component interconnects 171a, 172a, 171b, 172b may be coupled to the conductive structure 162 through solder and/or through direct metal-to-metal coupling. In some examples, the heights of the component interconnects 171a, 172a, 171b, 172b may be in the range of about 5 μm to about 50 μm.

In some examples, the electronic components 17a, 17b may comprise and/or be referred to as dies, chips, packages, functional/active components, passive components, controllers, processors, logics, memories, and/or memory stacks. In some examples, the electronic components 17a, 17b may be coupled to the conductive structure 162 by a mass reflow process, a thermal compression process, and/or a laser bonding process. In some examples, the heights of the electronic components 17a, 17b may be in the range of about 100 μm to about 1000 μm. The connect die 13 may reduce a signal path length between the first electronic component 17a and the second electronic component 17b and/or between the electronic components 17a, 17b and the external interconnects 19.

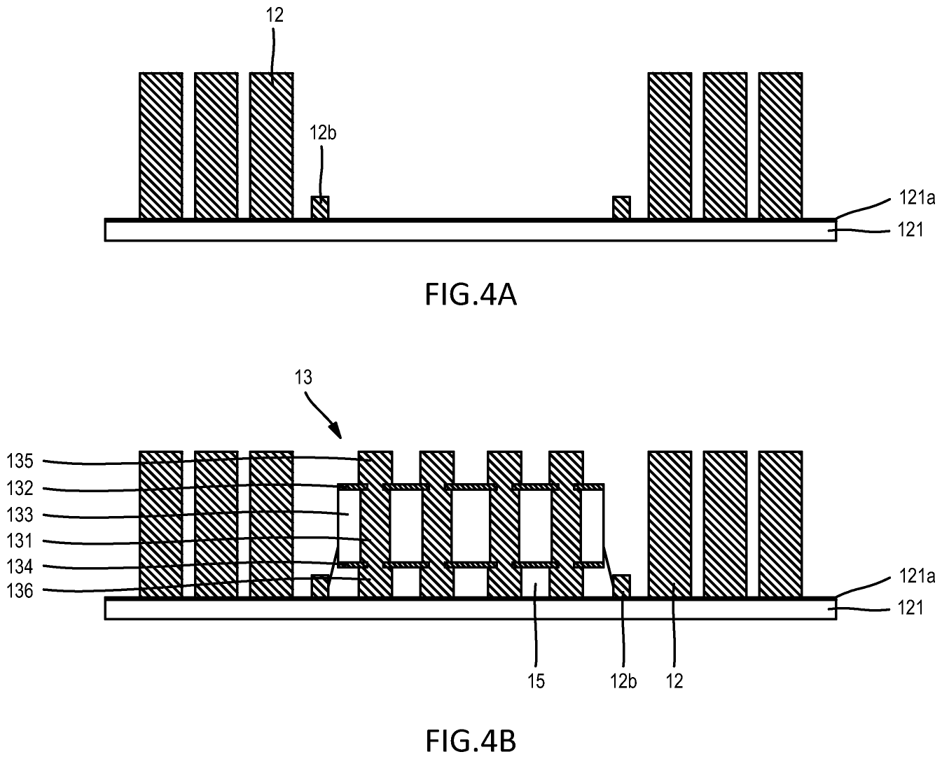

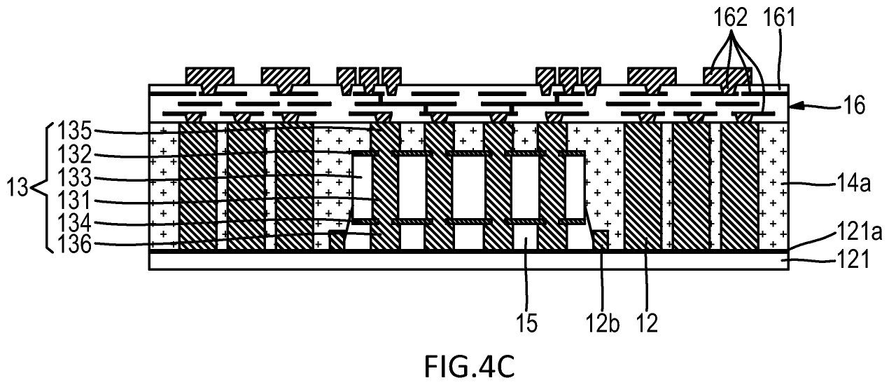

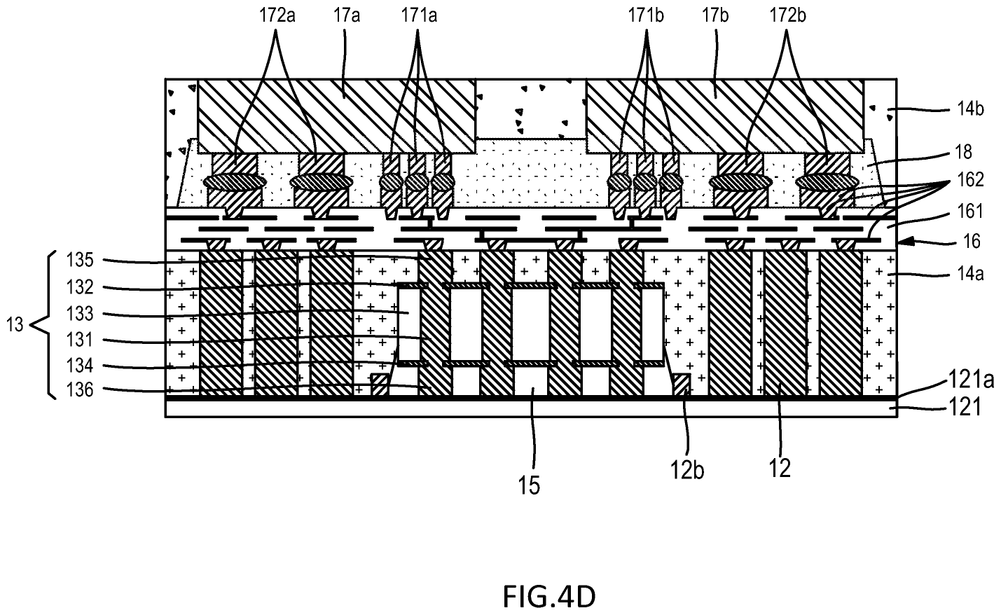

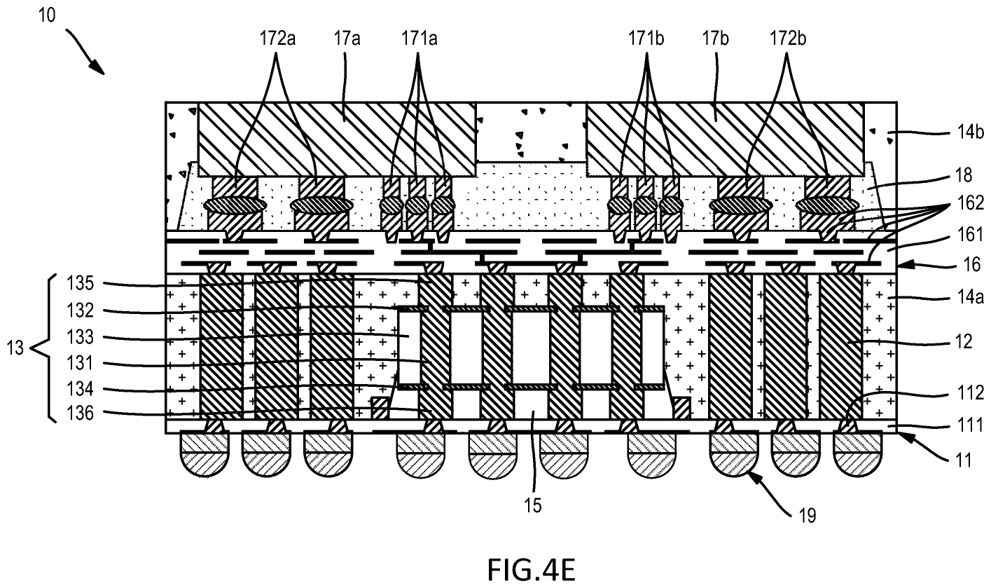

In some examples, the upper encapsulant 14b may be provided on the upper substrate 16. The upper encapsulant 14b may cover the electronic components 17a, 17b. Upper encapsulant 14b may comprise and/or be referred to as a mold material, a protective material, a mold compound, and/or a resin. In some examples, upper encapsulant 14b may comprise a polymer composite material, a polymer having an inorganic filler, an epoxy resin, an epoxy resin having a filler, an epoxy acrylate having a filler, and/or a silicone resin. In some examples, upper encapsulant 14b may be provided by a compression molding process, a vacuum lamination process, a liquid phase encapsulant molding process, a paste printing process, and/or a film assisted molding process. In some examples, the height of upper encapsulant 14b may be in the range of about 100 μm to about 1000 μm. In some examples, upper encapsulant 14b may fill a first gap between the first electronic components 17a and the upper substrate 16 and a second gap between the second electronic component 17b and the upper substrate 16. In some examples, an underfill 18 (FIG. 4D) may fill the first gap between the first electronic components 17a and the upper substrate 16 and the second gap between the second electronic component 17b and the upper substrate 16.

In some examples, the height and/or thickness of upper encapsulant 14b may be greater than the heights and/or thicknesses of the electronic components 17a, 17b. In this case, a grinding process and/or a chemical etching process for removing upper portions of the upper encapsulant 14b may be performed. In some examples, the upper sides of the electronic components 17a, 17b may be exposed at the upper side of upper encapsulant 14b by a grinding process. In some examples, the upper sides of the electronic components 17a, 17b may be coplanar with the upper side of upper encapsulant 14b. Upper encapsulant 14b may protect the electronic components 17a, 17b from exposure to external factors and/or environments.

FIG. 3E shows a cross-sectional view of the electronic device 10 at a later stage of manufacture. In the example shown in FIG. 3E, the device carrier 121, the seed layer 121a, and the alignment pads 12a are removed, thereby exposing a lower side of the connect die lower interconnects 136 and a lower side of the device interconnects 12. In some examples, a grinding process may be performed to remove the device carrier 121, the seed layer 121a, and the alignment pads 12a. The grinding process may also remove portions of the lower encapsulant 14a, the alignment features 12b, the connect die lower interconnects 136, and the device interconnects 12. In some examples, solder between the alignment pads 12a and the connect die lower interconnects 136 may also be ground or removed. In some examples, the alignment features 12b, the device interconnects 12, the connect die lower interconnects 136, and the interface material 15 may be exposed at the lower side of the lower encapsulant 14a.

FIG. 3F shows a cross-sectional view of the electronic device 10 at a later stage of manufacture. In the example shown in FIG. 3F, the lower substrate 11 may be provided. The lower substrate 11 may be provided on the lower side of the lower encapsulant 14a. In some examples, the lower substrate 11 may cover the device interconnects 12, the lower encapsulant 14a, and the connect die 13. The lower substrate 11 may comprise and/or be referred to as a redistribution structure. The lower substrate 11 may comprise a dielectric structure 111 and a conductive structure 112. In some examples, the thickness of the lower substrate 11 may be in the range of about 3 μm to about 50 μm.

The dielectric structure 111 of the lower substrate 11 may comprise and/or be referred to as one and/or more dielectrics, dielectric materials, dielectric layers, passivation layers, insulating layers, and/or protective layers. In some examples, the dielectric structure 111 may comprise polymer, PI, BCB, PBO, BT, a molding material, phenolic resin, epoxy, silicone and/or acrylate polymer. The dielectric structure 111 may be in contact with the device interconnects 12, the lower encapsulant 14a, the connect die 13, and the conductive structure 112 of the lower substrate 11. The dielectric structure 111 may expose a portion of the conductive structure 112. In some examples, the dielectric structure 111 may maintain the external shape of the lower substrate 11 and may structurally support the conductive structure 112. In some examples, the dielectric structure 111 may be provided by spin coating, spray coating, printing, oxidation, PVD, CVD, MOCVD, ALD, LPCVD, and/or PECVD. In some examples, the thickness of individual layers of the dielectric structure 111 may be in the range of about 1 μm to about 10 μm. The combined thickness of all layers of the dielectric structure 111 may define the thickness of the lower substrate 11.

The conductive structure 112 of the lower substrate 11 may comprise and/or be referred to as one and/or more conductors, conductive materials, conductive paths, conductive layers, RDLs, wiring layers, traces, vias, pads, and/or UBM. In some examples, the conductive structure 112 may comprise copper, aluminum, palladium, titanium, tungsten, titanium/tungsten, nickel, gold, and/or silver. The conductive structure 112 may be coupled to the connect die lower interconnects 136 and the device interconnects 12. The conductive structure 112 may transmit and/or redistribute signals, currents, and/or voltages within the lower substrate 11. In some examples, the thickness of the conductive structure 112 may be in the range of about 1 μm to about 10 μm. The thickness of the conductive structure 112 may refer to individual layers of the conductive structure 112.

In the example shown in FIG. 3F, the external interconnects 19 may be provided on the lower side of the lower substrate 11. In some examples, the external interconnects 19 may be coupled to the conductive structure 112 of the lower substrate 11. The external interconnects 19 may comprise and/or be referred to as solder balls, solder coated metal core balls (e.g., solder coated copper core balls), pillars, bumps, and/or copper pillars with solder caps, and/or copper bumps with solder caps. The external interconnects 19 may comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, and/or Sn—Ag—Cu. In some examples, the external interconnects 19 may be provided through a reflow process after forming a solder-containing conductive material on the lower side of the conductive structure 112 of the lower substrate 11 by a ball drop process. The external interconnects 19 may couple the electronic device 10 to an external device. In some examples, the thickness of the external interconnects 19 may be in the range of about 10 μm to about 100 μm. In accordance with various examples, after providing external interconnects 19, a singulation process (e.g., a sawing or cutting process) may be performed to provide individual electronic devices 10.

FIGS. 4A and 4E show cross-sectional views of an example method for manufacturing an example electronic device 10.

FIG. 4A shows a cross-sectional view of the electronic device 10 at an early stage of manufacture. In the example shown in FIG. 4A, the device interconnects 12 may be provided on a device carrier 121 provided with seed layer 121a. Alignment features 12b may be provided laterally between the device interconnects 12. The alignment pads 12a of FIG. 3A may be omitted from the device carrier 121 of FIG. 4A.

FIG. 4B shows a cross-sectional view of the electronic device 10 at a later stage of manufacture. In the example shown in FIG. 4B, the connect die 13 may be provided on the device carrier 121, and the interface material 15 may be provided between the connect die 13 and the device carrier 121. In some examples, the interface material 15 may comprise and/or be referred to as an adhesive, an adhesive tape, and/or an adhesive film. In some examples, the interface material 15 may comprise a heat-curable adhesive, a light-curable adhesive, and/or a non-curable adhesive (e.g., a rubber-based adhesive, an acrylic adhesive, a vinyl alkyl ether-based adhesive, a silicone-based adhesive, a polyester-based adhesive, a polyamide-based adhesive, and/or a urethane-based adhesive). The interface material 15 may surround the connect die lower interconnects 136. In some examples, after the interface material 15 is provided on the lower side of the connect die 13, the connect die 13 may be attached to the device carrier 121. In some examples, the interface material 15 may serve to couple the connect die 13 to the device carrier 121. The connect die lower interconnects 136 may penetrate the interface material 15 to then come into contact with the seed layer 121a.

FIG. 4C shows a cross-sectional view of the electronic device 10 at a later stage of manufacture. The components and steps shown in FIG. 4C may correspond to the components and steps shown in FIG. 3C. In the example shown in FIG. 4C, the lower encapsulant 14a may be provided on the device carrier 121, and the upper substrate 16 may be provided on the lower encapsulant 14a and connect die 13.

FIG. 4D shows a cross-sectional view of the electronic device 10 at a later stage of manufacture. The components and manufacturing steps shown in FIG. 4D may correspond to the components and manufacturing steps shown in FIG. 3D. In the example shown in FIG. 4D, the electronic components 17a, 17b may be provided on the upper substrate 16.

In some examples, an underfill 18 may be provided between the electronic components 17a, 17b and the upper substrate 16. Underfill 18 may comprise and/or be referred to as CUF, MUF, NCP, NCF, and/or ACF. In some examples, the underfill 18 may comprise epoxy, a thermoplastic material, a thermosetting material, polyimide, polyurethane, a polymeric material, filled epoxy, a filled thermoplastic material, a filled thermosetting material, filled polyimide, filled polyurethane, a filled polymeric material, and/or a fluxing underfill. The underfill 18 may cover the conductive structure 162 of the upper substrate 16 and the component interconnects 171a, 172a, 171b, 172b. The underfill 18 may be in contact with the upper side of the upper substrate 16 and the lower sides of the electronic components 17a, 17b. In some examples, the underfill 18 may cover portions of the lateral sides of the electronic components 17a, 17b. In some examples, the underfill 18 may prevent the electronic components 17a, 17b from being separated from the upper substrate 16 by physical and/or chemical impact. In some examples, the thickness of the underfill 18 may be in the range of about 5 μm to about 50 μm.

In some examples, the upper encapsulant 14b may be provided on the upper substrate 16. The upper encapsulant 14b may cover the electronic components 17a, 17b and underfill 18. Upper encapsulant 14b may comprise and/or be referred to as a mold material, a protective material, a mold compound, and/or a resin. In some examples, upper encapsulant 14b may comprise a polymer composite material, a polymer having an inorganic filler, an epoxy resin, an epoxy resin having a filler, an epoxy acrylate having a filler, and/or a silicone resin. In some examples, upper encapsulant 14b may be provided by a compression molding process, a vacuum lamination process, a liquid phase encapsulant molding process, a paste printing process, and/or a film assisted molding process. In some examples, the height of upper encapsulant 14b may be in the range of about 100 μm to about 1000 μm.

In some examples, the height and/or thickness of upper encapsulant 14b may be greater than the heights and/or thicknesses of the electronic components 17a, 17b. In this case, a grinding process and/or a chemical etching process for removing upper portions of the upper encapsulant 14b may be performed. In some examples, the upper sides of the electronic components 17a, 17b may be exposed at the upper side of upper encapsulant 14b by a grinding process. In some examples, the upper sides of the electronic components 17a, 17b may be coplanar with the upper side of upper encapsulant 14b. Upper encapsulant 14b may protect the electronic components 17a, 17b from exposure to external factors and/or environments.

FIG. 4E shows a cross-sectional view of the electronic device 10 at a later stage of manufacture. The components and manufacturing steps shown in FIG. 4D may correspond to the components and manufacturing steps shown in FIGS. 3E and 3F. In the example shown in FIG. 4E, the device carrier 121 may be removed. In some examples, the device carrier 121 may be removed from the device interconnects 12, the connect die 13, and the lower encapsulant 14a by a grinding process, an etching process, and/or a light/heat providing process. The seed layer 121a on the device carrier 121 may also be removed. After separating and/or removing the device carrier 121 and the seed layer 121a, the alignment features 12b, the device interconnects 12, the connect die lower interconnects 136, and the interface material 15 may be exposed at the lower side of the lower encapsulant 14a.

In accordance with various examples, after removing device carrier 121, the lower substrate 11 may be provided on the lower side of the lower encapsulant 14a, and the external interconnects 19 may be provided on the lower side of the lower substrate 11. In accordance with various examples, after providing external interconnects 19, a singulation process (e.g., a sawing or cutting process) may be performed to provide individual electronic devices 10.

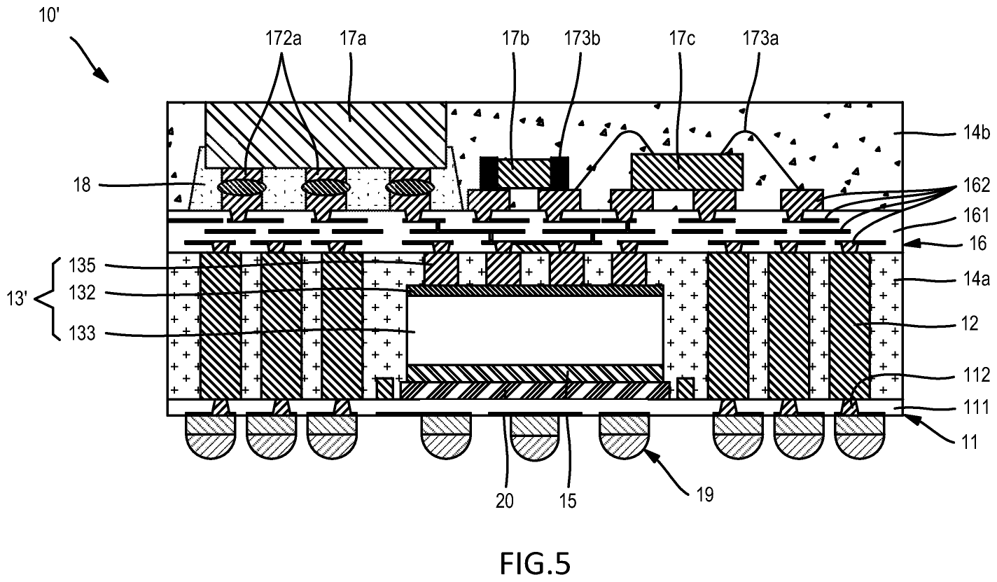

FIG. 5 shows a cross-sectional view of an example electronic device 10′. In the example shown in FIG. 5, electronic device 10′ may comprise the lower substrate 11, the device interconnects 12, a connect die 13′, the lower encapsulant 14a, the upper encapsulant 14b, the interface material 15, the upper substrate 16, the electronic components 17a, 17b, the underfill 18, the external interconnects 19, and a base block 20. In some examples, the electronic device 10′ may comprise similar elements, features, materials, and/or formation processes to those of electronic device 10, as previously described.

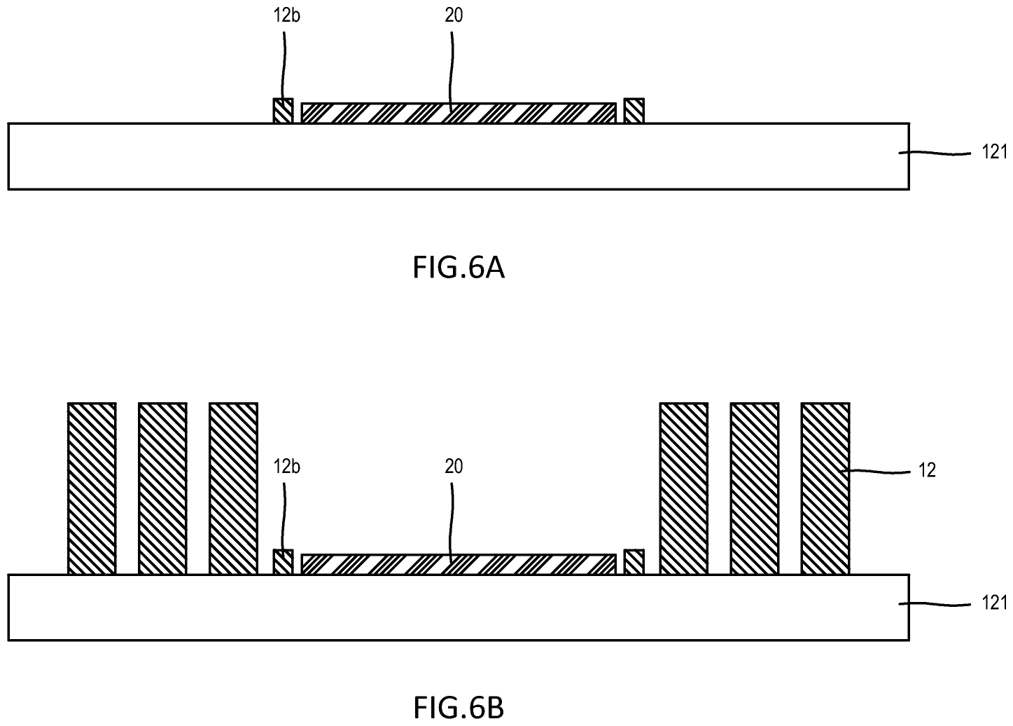

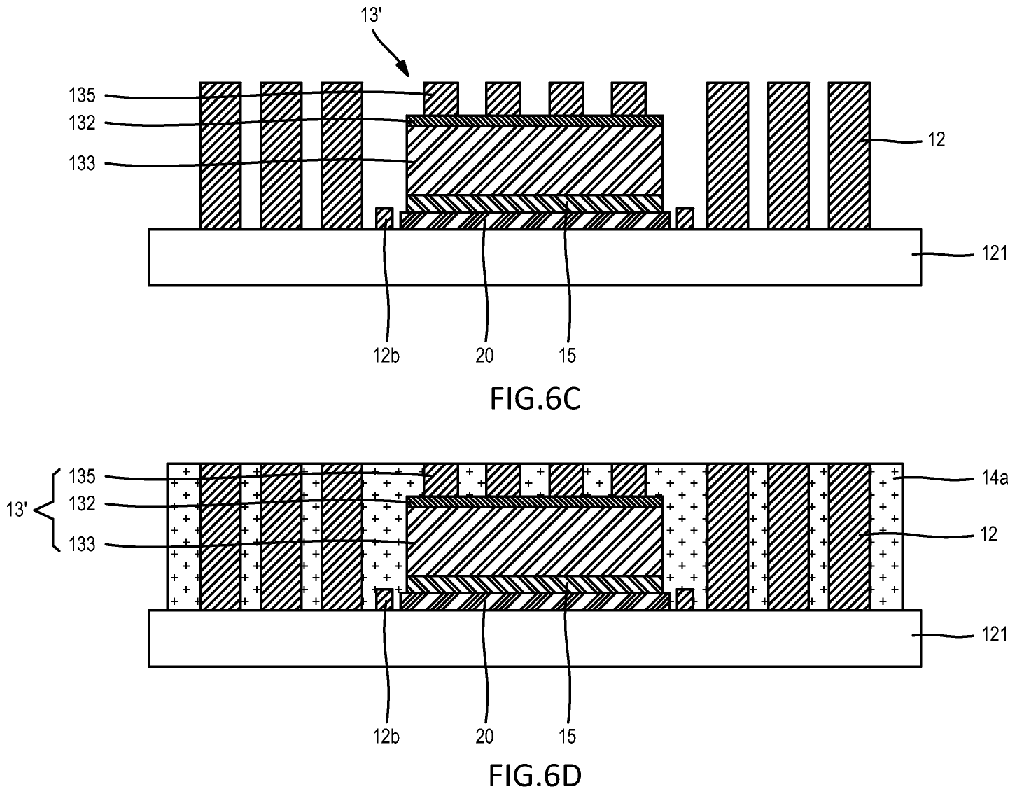

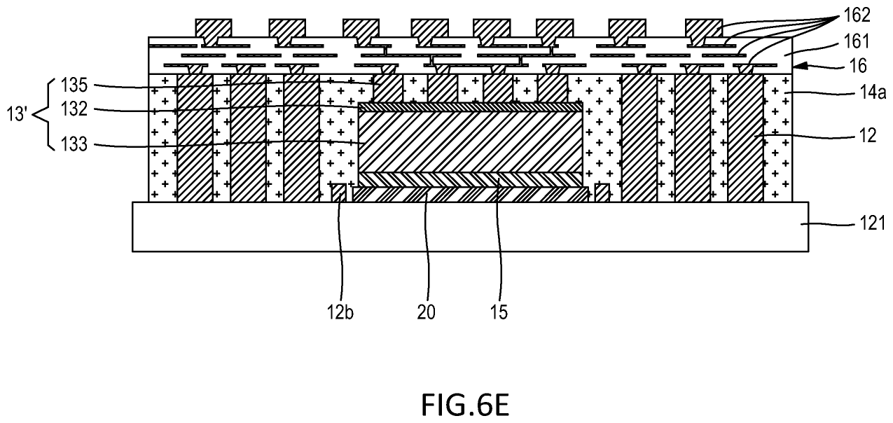

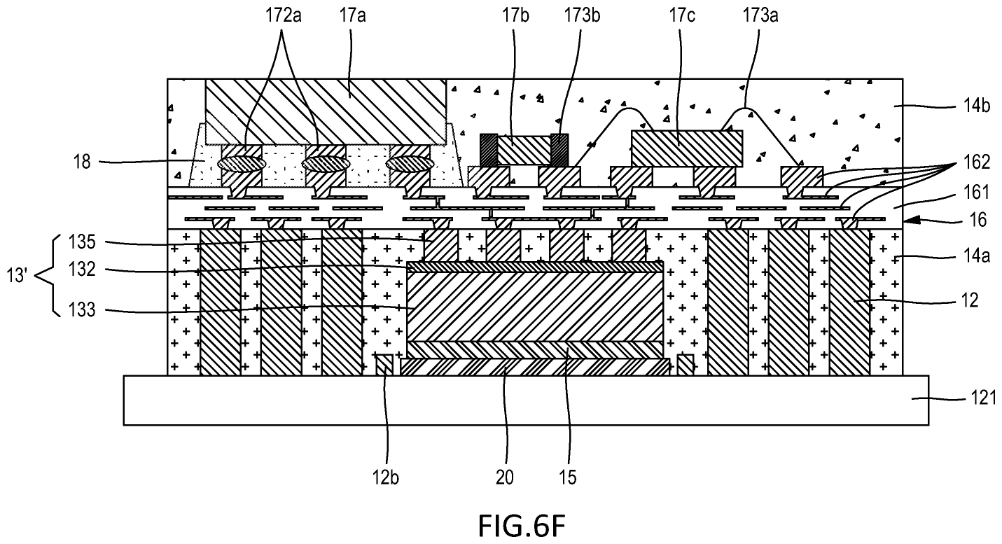

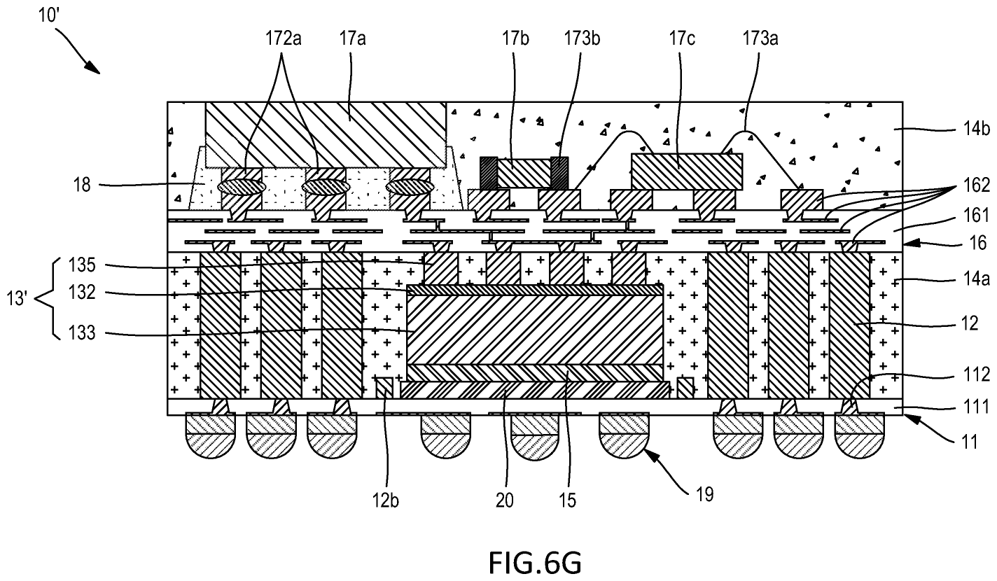

FIGS. 6A to 6G show cross-sectional views of an example method for manufacturing an example electronic device 10′.

FIG. 6A shows a cross-sectional view of the electronic device 10′ at an early stage of manufacture. In the example shown in FIG. 6A, the base block 20 may be provided on the device carrier 121. In some examples, the base block 20 may comprise and/or be referred to as a passivation block and/or a dielectric block. In some examples, the base block 20 may comprise a dielectric material such as an all standard polyimide material (e.g., BL-301, HD4100, HD4110, LTC9310, and/or LTC9320). In some examples, the thickness of the base block 20 may be in the range of about 5 μm to about 11 μm.

In some examples, the alignment features 12b may be provided on the device carrier 121. The alignment features 12b may be provided beyond a periphery of the base block 20. In some examples, the alignment features 12b may be provided over the device carrier 121 at the same time as the base block 20.

FIG. 6B shows a cross-sectional view of the electronic device 10′ at a later stage of manufacture. In the example shown in FIG. 6B, the device interconnects 12 may be provided on the device carrier 121. In some examples, the device interconnects 12 may be provided beyond the periphery of the base block 20.

FIG. 6C shows a cross-sectional view of electronic device 10′ at a later stage of manufacture. In the example shown in FIG. 6C, the connect die 13′ may be provided on the base block 20. In some examples, the connect die 13′ may be seated on the base block 20. In some examples, the area “or “footprint”) of the base block 20 may correspond to the area (or “footprint”) of the connect die 13′. In some examples, the connect die 13′ may be attached and/or coupled to the base block 20 through the interface material 15. The interface material 15 may be provided between connect die 13′ and the base block 20. In some examples, the interface material 15 may comprise and/or be referred to as a die attach film (DAF), an adhesive film, and/or an adhesive tape. In some examples, the interface material 15 may entirely cover the lower side of the connect die 13′. In some examples, the interface material 15 may serve to attach the connect die 13′ to the base block 20. In some examples, the thickness of the interface material 15 may be in the range of about 5 μm to about 50 μm. In some examples, the base block 20 may prevent and/or protect the interface material 15′ from being damaged during later processing.

The connect die 13′ may comprise the connect die upper RDS 132, the connect die body 133, and the connect die upper interconnects 135. In some examples, the connect die 13′ may comprise similar elements, features, materials, and/or formation processes to those of the connect die 13, as previously described. In some examples, the connect die interconnects 131, the connect die lower RDS 134, and the connect die lower interconnects 136 of connect die 13 of FIG. 2M may be omitted from the connect die 13′.

FIG. 6D shows a cross-sectional view of the electronic device 10′ at a later stage of manufacture. In the example shown in FIG. 6D, the lower encapsulant 14a may be provided on the device carrier 121 and may encapsulate the device interconnects 12 and the connect die 13′. In some examples, the height and/or thickness of the lower encapsulant 14a may be greater than the height and/or thickness of the device interconnects 12 and/or the height and/or thickness of the connect die 13′. In this case, a grinding process and/or a chemical etching process for removing upper portions of the lower encapsulant 14a may be performed. In some examples, the upper sides of the device interconnects 12 and the upper sides of the connect die upper interconnects 135 may be exposed at the upper side of the lower encapsulant 14a.

FIG. 6E shows a cross-sectional view of the electronic device 10′ at a later stage of manufacture. In the example shown in FIG. 6E, the upper substrate 16 may be provided on the upper side of the lower encapsulant 14a. The components and steps shown in FIG. 6E may correspond to components and steps shown in FIG. 3C.

FIG. 6F shows a cross-sectional view of electronic device 10′ at a later stage of manufacture. In the example shown in FIG. 6F, electronic components 17a, 17b, 17c may be provided on the upper substrate 16. The electronic components 17a, 17b, 17c may be coupled to the conductive structure 162 of the upper substrate 16.

In some examples, third component interconnects 173a of the third electronic component 17c may comprise bond wires. In particular, the bond wires of the third component interconnects 173a may couple an upper side of the third electronic component 17c to the conductive structure 162 of the upper substrate 16. The second electronic component 17b may comprise second component interconnects 173b. In some examples, second component interconnects 173b may be provided at both sides of the second electronic component 17b. The second component interconnects 173b may be coupled to the conductive structure 162 of the upper substrate 16. In some examples, the second electronic component 17b may comprise a passive device and/or a passive component. For example, the second electronic component 17b may comprise a capacitor, an inductor, and/or a resistor. In some examples, the underfill 18 may be provided between the first electronic component 17a and the upper substrate 16, and the upper encapsulant 14b may be provided on the upper substrate 16.

FIG. 6G shows a cross-sectional view of the electronic device 10′ at a later stage of manufacture. In the example shown in FIG. 6G, the device carrier 121 may be removed and the lower substrate 11 may be provided on the lower side of the lower encapsulant 14a. In some examples, the device carrier 121 may be removed after providing upper encapsulant 14b. In some examples, the device carrier 121 may be removed by grinding and/or wet etching, and the base block 20, the device interconnects 12, and the alignment features 12b may be exposed at the lower side of the lower encapsulant 14a. In some examples, when removing the device carrier 121, portions of the base block 20, the device interconnects 12, the alignment features 12b, and the lower encapsulant 14a may be removed together by the grinding process. Here, the base block 20 may protect the interface material 15 and may improve the quality of the grinding process.

In some examples, the lower substrate 11 may cover the base block 20, the device interconnects 12, the alignment features 12b, and the lower encapsulant 14a. The dielectric structure 111 of the lower substrate 11 may contact the base block 20. In accordance with various examples, the external interconnects 19 may be provided on the lower side of the lower substrate 11. After providing external interconnects 19, a singulation process (e.g., a sawing or cutting process) may be performed to provide individual electronic devices 10′.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A method of manufacturing an electronic device, the method comprising:
providing a first device interconnect, a second device interconnect, and alignment pads, wherein the alignment pads are laterally between the first device interconnect and the second device interconnect;
coupling connect die lower interconnects of a connect die to the alignment pads;
encapsulating the connect die, the first device interconnect, and the second device interconnect with a lower encapsulant;
providing an upper substrate on the lower encapsulant such that a conductive structure of the upper substrate is coupled to the first device interconnect, the second device interconnect, and connect die upper interconnects of the connect die; and
coupling a first electronic component and a second electronic component to the upper substrate such that the first electronic component is electrically coupled to the second electronic component via the connect die.

2. The method of claim 1, wherein:
the first device interconnect, the second device interconnect, and the alignment pads are provided on an upper side of a device carrier; and
the method comprises:
providing a first alignment feature and a second alignment feature on the upper side of the device carrier, wherein the first alignment feature is laterally between the first device interconnect and the alignment pads and the second alignment feature is laterally between the second device interconnect and the alignment pads; and
filling, with an interface material, a gap between a lower side of the connect die and the upper side of the device carrier such that the interface material is laterally retained between an inner lateral side of the first alignment feature and an inner lateral side of the second alignment feature.

3. The method of claim 1, wherein:
the first device interconnect, the second device interconnect, and the alignment pads are provided on an upper side of a device carrier; and
the method comprises:
providing a first alignment feature and a second alignment feature on the upper side of the device carrier, wherein the first alignment feature is laterally between the first device interconnect and the alignment pads and the second alignment feature is laterally between the second device interconnect and the alignment pads; and
filling, with an interface material, a gap between a lower side of the connect die and the upper side of the device carrier such that the interface material encapsulates the connect die lower interconnects and the alignment pads.

4. The method of claim 1, wherein coupling the first electronic component and the second electronic component to the upper substrate comprises:
coupling the first electronic component to the upper substrate via first component fine-pitch interconnects and first component coarse-pitch interconnects such that the first electronic component is coupled to the connect die via the first component fine-pitch interconnects; and
coupling the second electronic component to the upper substrate via second component fine-pitch interconnects and second component coarse-pitch interconnects such that the second electronic component is coupled to the first electronic component via the second component fine-pitch interconnects and the connect die.

5. The method of claim 1, comprising providing a lower substrate on a lower side of the lower encapsulant such that a conductive structure of the lower substrate is coupled to the first device interconnect, the second device interconnect, and the connect die lower interconnects.

6. The method of claim 5, comprising providing external interconnects on a lower side of the lower substrate such that at least one of the external interconnects is electrically coupled to at least one of the connect die lower interconnects via the lower substrate.

7. The method of claim 1, comprising filling a first gap between the first electronic component and the upper substrate and a second gap between the second electronic component and the upper substrate with an underfill.

8. The method of claim 1, comprising:
filling a first gap between the first electronic component and the upper substrate and a second gap between the second electronic component and the upper substrate with an underfill; and
encapsulating the first electronic component, the second electronic component, and the underfill with an upper encapsulant.

9. The method of claim 1, wherein:
the connect die comprises:
a connect die body comprising a connect die body upper side and a connect die body lower side;
connect die interconnects that pass between the connect die body upper side and the connect die body lower side;
connect die pads on the connect die body lower side and coupled to lower ends of the connect die interconnects; and
a connect die insulating layer on the connect die body lower side, wherein the connect die insulating layer laterally encapsulates lateral sidewalls of the connect die pads;
the connect die upper interconnects are on the connect die body upper side;
the connect die lower interconnects are on the connect die body lower side and coupled to respective ones of the connect die pads; and
one or more of the connect die upper interconnects are coupled to one or more of the connect die lower interconnects via the connect die interconnect through the connect die body and the connect die pads.

10. A method of manufacturing an electronic device, the method comprising:
providing a first device interconnect, a second device interconnect, and a base block, wherein the base block is laterally between the first device interconnect and the second device interconnect;
coupling a lower side of a connect die to an upper side of the base block;
encapsulating the connect die, the first device interconnect, and the second device interconnect with a lower encapsulant;
providing an upper substrate on the lower encapsulant such that a conductive structure of the upper substrate is coupled to the first device interconnect, the second device interconnect, and connect die upper interconnect of the connect die; and
coupling a first electronic component and a second electronic component to the upper substrate such that the first electronic component is electrically coupled to the second electronic component via the connect die.

11. The method of claim 10, wherein coupling the lower side of the connect die comprises coupling the lower side of the connect die to the upper side of the base block through an interface material.

12. The method of claim 10, wherein coupling the lower side of the connect die comprises coupling the lower side of the connect die to the upper side of the base block through a die attach film, an adhesive film, and/or an adhesive tape.

13. The method of claim 10, wherein coupling the first electronic component and the second electronic component to the upper substrate comprises:
coupling a lower side of the first electronic component to the upper substrate via first component interconnects; and
coupling an upper side of the second electronic component to the upper substrate via bond wires.

14. The method of claim 10, comprising:
providing a lower substrate on a lower side of the lower encapsulant such that a conductive structure of the lower substrate is coupled to the first device interconnect and the second device interconnect; and
providing external interconnects on a lower side of the lower substrate such that at least one of the external interconnects is electrically coupled to the first device interconnect via the lower substrate.

15. An electronic device comprising:
a lower substrate comprising a lower substrate upper side and a lower substrate lower side;
an upper substrate comprising an upper substrate upper side and an upper substrate lower side;
a first electronic component and a second electronic component coupled to the upper substrate upper side;
a first device interconnect and a second device interconnect that couple the lower substrate upper side to the upper substrate lower side; and
a connect die coupled to the lower substrate upper side laterally between the first device interconnect and the second device interconnect, wherein the connect die electrically couples the first electronic component to the second electronic component.

16. The electronic device of claim 15, wherein the connect die comprises:
a connect die body comprising a connect die body upper side and a connect die body lower side;
connect die interconnects that pass between the connect die body upper side and the connect die body lower side;
connect die pads on the connect die body lower side and coupled to lower ends of the connect die interconnects;
a connect die insulating layer on the connect die body lower side, wherein the connect die insulating layer laterally encapsulates lateral sidewalls of the connect die pads;
connect die upper interconnects on the connect die body upper side; and
connect die lower interconnects on the connect die body lower side and coupled to respective ones of the connect die pads; and
wherein one or more of the connect die upper interconnects are coupled to one or more of the connect die lower interconnects via the connect die interconnect through the connect die body and the connect die pads.

17. The electronic device of claim 15, comprising:
a base block laterally between the first device interconnect and the second device interconnect; and
wherein a lower side of the connect die is coupled to an upper side of the base block.

18. The electronic device of claim 15, comprising:
first component fine-pitch interconnects and first component coarse-pitch interconnects that coupled the first electronic component to the upper substrate; and
second component fine-pitch interconnects and second component coarse-pitch interconnects that coupled the second electronic component to the upper substrate; and
wherein the connect die couples the first electronic component to the second electronic component via the first component fine-pitch interconnects and the second component fine-pitch interconnects.

19. The electronic device of claim 15, comprising an underfill that fills a first gap between the first electronic component and the upper substrate and a second gap between the second electronic component and the upper substrate.

20. The electronic device of claim 19, comprising:
an upper encapsulant that encapsulates the first electronic component, the second electronic component, and the underfill; and
a lower encapsulant that encapsulates the connect die, the first device interconnect, and the second device interconnect.
